(19) United States
(12) Patent Application Publication
(10) Pub. No.: US 2026/0088247 A1
(43) Pub. Date: Mar. 26, 2026

(54) SCANNING ELECTRON MICROSCOPE WITH ENHANCED THREE-DIMENSIONAL IMAGING

(71) Applicant: Samsung Electronics Co., Ltd., Suwon-si (KR)

(72) Inventors: Hyeon Bo Shim, Suwon-si (KR); Souk Kim, Suwon-si (KR); Younghoon Sohn, Suwon-si (KR); Yongdeok Jeong, Suwon-si (KR)

(21) Appl. No.: 19/191,412

(22) Filed: Apr. 28, 2025

(30) Foreign Application Priority Data
Sep. 25, 2024 (KR) 10-2024-0130212

(51) Int. Cl. H01J 37/22; H01J 37/10; H01J 37/147; H01J 37/244; H01J 37/28

(52) U.S. Cl. CPC H01J 37/222; H01J 37/10; H01J 37/147; H01J 37/244; H01J 37/28; H01J 2237/221

(57) ABSTRACT

A scanning electron microscope configured to generate an image by scanning an input electron beam to a sample and detecting emitted electrons emitted from the sample. The microscope includes an inductive unit configured to induce the emitted electrons with an electric field, a variable magnetic unit configured to change a path of the emitted electrons induced by the inductive unit by using a magnetic field, a detection unit configured to generate an image by detecting the emitted electrons having a changed path, and a signal processing unit configured to derive three-dimensional structural information of the sample by using the image and the magnetic field.

### REFERENCE TO PRIORITY APPLICATION

This application claims priority under 35 U.S.C. § 119 to Korean Patent Application No. 10-2024-0130212, filed Sep. 25, 2024, the disclosure of which is hereby incorporated herein by reference.

### BACKGROUND

The inventive concept relates to scanning electron microscope technology and methods of operating same.

A scanning electron microscope (SEM) is a type of electron microscope that scans and images the surface of a sample with an electron beam (E-beam). An SEM typically emits electrons using a high-speed electron gun, and the electrons may detect particles, such as secondary electrons, emitted by a sample while colliding and interacting with the surface of the sample. An SEM may analyze topographical information about the surface shape of a sample, morphological information such as the shapes and sizes of particles configuring a sample, and crystallographic information such as the arrangement of atoms within a sample.

SEMs have allowed observation of micro-structures that were impossible to measure due to the resolution limitations of optical microscopes, and thus SEMs are often applied in a wide range of fields, such as medicine, biotechnology, biology, microbiology, materials engineering, food engineering, or the like.

### SUMMARY

The inventive concept provides a scanning electron microscope (SEM) that can measure a three-dimensional structure.

In addition, objectives of the inventive concept are not limited to the above, and other objectives may be clearly understood by those skilled in the art from the following description.

According to an embodiment of the inventive concept, there is provided a scanning electron microscope configured to generate an image by scanning an input electron beam onto a sample and detecting emitted electrons emitted from the sample. The scanning electron microscope may include an inductive unit configured to influence the emitted electrons using an electric field, a variable magnetic unit configured to change a path of the emitted electrons affected by the inductive unit using a magnetic field, a detection unit configured to generate an image by detecting the emitted electrons having a changed path, and a signal processing unit configured to derive three-dimensional structural information of the sample by using the image and the magnetic field.

According to a further embodiment of the inventive concept, there is provided a scanning electron microscope including an electron beam scanning module configured to scan an input electron beam onto a sample, an emitted electron detection module configured to change and detect a path of emitted electrons emitted from the sample by the input electron beam by using a magnetic field, a controller configured to control the electron beam scanning module to allow the input electron beam to be irradiated to a certain position on the sample and to control a magnitude of the magnetic field generated by the emitted electron detection module, and a signal processing unit configured to derive three-dimensional structural information of the sample by using an image and the magnetic field.

According to another embodiment of the inventive concept, there is provided a scanning electron microscope including an electron gun configured to generate an input electron beam and scan the input electron beam onto a sample, a stage configured to support the sample, a focusing lens arranged between the electron gun and the sample and configured to focus the input electron beam, a deflector arranged between the focusing lens and the sample and configured to deflect the input electron beam, an objective lens arranged between the deflector and the sample and configured to focus the input electron beam onto the sample, an inductive unit configured to induce emitted electrons with a magnetic field, a variable magnetic unit configured to change a path of the emitted electrons induced by the inductive unit by using a magnetic field, a detection unit configured to generate an image by detecting the emitted electrons having a changed path, a controller configured to control the input electron beam to be irradiated to a certain position on the sample and to control a magnitude of the magnetic field generated by the variable magnetic unit, and a signal processing unit configured to derive three-dimensional structural information of the sample by using the image and the magnetic field.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a scanning electron microscope according to an embodiment;

FIG. 2 is a functional block diagram illustrating the configuration of a signal processing unit according to an embodiment;

FIG. 3 is a diagram to describe a process in which emitted electrons are detected through an emitted electron detection module;

FIGS. 4A and 4B are diagrams to describe emission paths of emitted electrons when the kinetic energy of the emitted electrons is low and high, respectively;

FIGS. 5A and 5B are diagrams to describe scanning electron microscope (SEM) images obtained when the depth and critical dimension (CD) of a pattern are different;

FIGS. 6A to 9B are diagrams to describe SEM images formed by emitted electrons with relatively high kinetic energy and emitted electrons with relatively low kinetic energy according to a three-dimensional structure of a pattern;

FIG. 10 is a flowchart to describe a method of obtaining a three-dimensional SEM image by using an SEM, according to an embodiment; and

FIG. 11 is a conceptual diagram to describe a method of manufacturing a semiconductor device by using an SEM, according to an embodiment.

### DETAILED DESCRIPTION OF EMBODIMENTS

The inventive concept will now be described more fully with reference to the accompanying drawings, in which embodiments of the inventive concept are shown. Like reference numerals in the drawings denote like elements, and thus their description will be omitted.

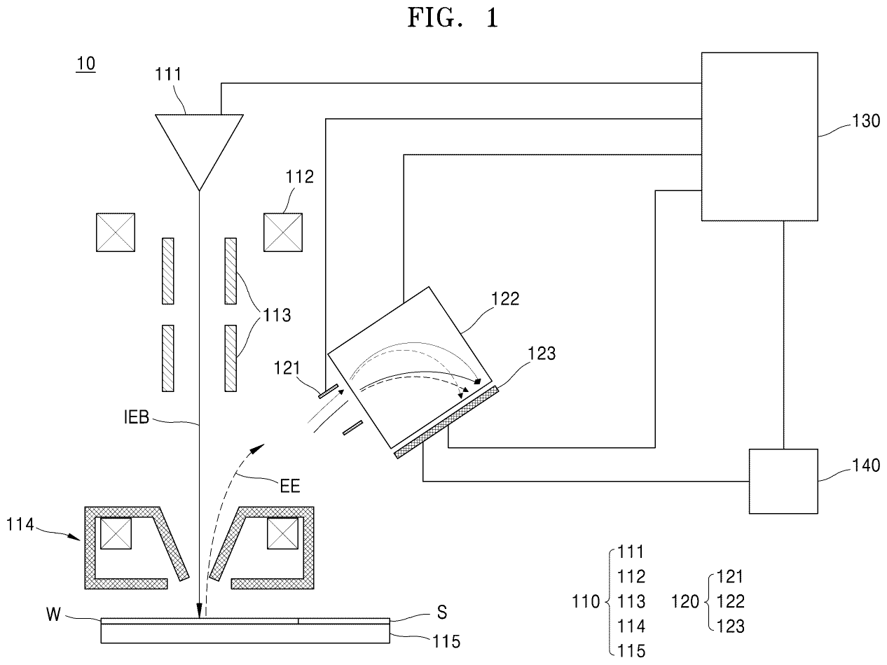

FIG. 1 is a configuration diagram of a scanning electron microscope (SEM) according to an embodiment. Referring to FIG. 1, an SEM 10 may be configured to measure a wafer W (on which a manufacturing process of a semiconductor device has been performed) by scanning. According to embodiments, the SEM 10 may obtain topographical information about the wafer W, morphological information such as the shapes and sizes of particles configuring the wafer W, and crystallographic information such as the arrangement status of atoms within the wafer W, by measuring the wafer W.

According to embodiments, the SEM 10 may evaluate the manufacturing process of a semiconductor device formed on the wafer W by irradiating an input electron beam IEB onto the wafer W and detecting emitted electrons EE emitted from the wafer W in response to interaction between the input electron beam IEB and the wafer W. The emitted electrons EE may be generated by elastic scattering and/or inelastic scattering.

Elastic scattering is a phenomenon in which electrons included in the input electron beam IEB are directed in an opposite direction to an input direction of the input electron beam IEB without any substantial change in energy of the electrons included in the input electron beam IEB due to the potential of atomic nuclei configuring the wafer W. Electrons that escape from the surface of the wafer W by elastic scattering are referred to as backscattered electrons, and the backscattered electrons may have energy of about 50 eV or more. The backscattered electrons may include information about the structure and composition near the surface of the wafer W.

Inelastic scattering is a phenomenon in which electrons included in the input electron beam IEB interact with electrons in electron orbits of atoms within the wafer W when being incident on the surface of the wafer W, causing electrons included within atoms within the wafer W to be emitted. Secondary electrons, Auger electrons, and X-rays may be emitted by inelastic scattering. Among the emitted electrons EE, secondary electrons may have energy of several eVs. The secondary electrons may include information about the unevenness near the surface of the wafer W.

As will be understood by those skilled in the art, secondary electrons are generated when energy is transferred to electrons bound to the atoms within the wafer W by the electrons included in the input electron beam IEB, and the electrons bound to the atoms are emitted as free electrons. When electrons at energy levels lower than the valence band are emitted in the form of secondary electrons, electrons at higher energy levels are configured to undergo de-excitation to lower energy levels, thereby emitting X-rays. The electrons emitted from the wafer W resulting from such X-ray emission are capable of being Auger electrons. The X-rays may include continuum X-rays and characteristic X-rays. The Auger electrons and the X-rays may include information about the composition and chemical bonding near the surface of the wafer W. In addition, the SEM 10 may further detect signals from incoherent elastic scattering, transmitted electrons, and cathodoluminescence.

In some embodiments, the SEM 10 may include an electron beam scanning module 110, an emitted electron detection module 120, a controller 130, and a signal processing unit 140. The electron beam scanning module 110 may scan the input electron beam IEB onto a sample. The electron beam scanning module 110 may include, for example, an electron gun 111, a focusing lens 112, a deflector 113, an objective lens 114, and a stage 115.

The electron gun 111 may generate and emit the input electron beam IEB. The input electron beam IEB emitted from the electron gun 111 may be irradiated onto a sample S. In an embodiment, the electron gun 111 may be configured to irradiate the input electron beam IEB onto the wafer W and the sample S. A wavelength of the input electron beam IEB may be determined by the energy of electrons emitted from the electron gun 111. According to embodiments, the wavelength of the input electron beam IEB may be several nm. According to embodiments, the electron gun 111 may be any one of a cold field emission (CPE) type, a Schottky emission (SE) type, and a thermionic emission (TE) type.

The electron gun 111 may generate the input electron beam IEB by thermally or electrically applying energy at a work function energy level (that is, a difference value between an energy level in a vacuum and Fermi energy), or higher, to electrons included in a solid material, which is an electron source.

The focusing lens 112 may be arranged on a path of the input electron beam IEB between the electron gun 111 and the wafer W. According to embodiments, the focusing lens 112 may focus the input electron beam IEB onto the deflector 113. Accordingly, the controllability of the input electron beam IEB may be improved by the deflector 113. The deflector 113 may be arranged on the path of the input electron beam IEB between the focusing lens 112 and the wafer W. The deflector 113 may deflect the input electron beam IEB emitted from the electron gun 111. The deflector 113 may deflect the input electron beam IEB so that the input electron beam IEB passes through the focusing lens 112 and the objective lens 114 to be irradiated to a set position on the wafer W and/or the sample S. According to embodiments, the deflector 113 may scan the input electron beam IEB on the wafer W and/or the sample S. The deflector 113 may be either of an electric type or a magnetic type.

The objective lens 114 may be arranged on the path of the input electron beam IEB between the deflector 113 and the wafer W. The objective lens 114 may focus the input electron beam IEB on the wafer W and/or the sample S. As the input electron beam IEB is limited to a narrow region on the wafer W and/or the sample S, the resolution of the SEM 10 may be further improved.

In the above, a transfer system of the input electron beam IEB including the focusing lens 112, the deflector 113, and the objective lens 114 has been described, but this is a non-limiting example, and the inventive concept is not limited thereto. Those skilled in the art will easily implement the transfer system of the input electron beam IEB including additional focusing lenses and additional deflectors based on the above description.

The stage 115 may support the wafer W and the stage 115, which are objects to be measured. The stage 115 may move the wafer W and/or the sample S in horizontal and vertical directions or rotate the wafer W and/or the sample S by using a vertical direction as an axis so that the wafer W and/or the sample S are aligned with respect to an optical system (that is, an optical system including the electron gun 111, the focusing lens 112, the deflector 113, and the objective lens 114) that transfers the input electron beam IEB. For example, the sample S on the stage 115 may be arranged on one side of the wafer W. The sample S may include a plurality of samples. Each sample may be a coupon sample for the structure of a semiconductor device. For example, each sample may be a coupon sample for a memory repeating pattern structure, such as a pillar, a hole, a line, and/or a space.

The emitted electron detection module 120 may detect emitted electrons EE from the sample S by deflecting their path using a magnetic field, wherein the emitted electrons EE may be generated upon irradiation of an input electron beam IEB onto the sample S. As shown, the emitted electron detection module 120 may include, for example, an inductive unit 121, a variable magnetic unit 122, and a detection unit 123.

The inductive unit 121 may induce/direct the emitted electrons EE to the variable magnetic unit 122. In detail, the inductive unit 121 may change a travelling direction of the emitted electrons EE emitted from the sample S by generating an electric field. The emitted electrons EE emitted from the sample S may be influenced by the electric field generated by the inductive unit 121 to change the travelling direction thereof toward the inductive unit 121, and may pass through the inductive unit 121 and travel toward the variable magnetic unit 122.

The inductive unit 121 may have a positive charge. Because the emitted electrons EE have a negative charge, the emitted electrons EE may travel toward the inductive unit 121 having a positive charge. The inductive unit 121 may have a column shape with open upper and bottom surfaces. The inductive unit 121 may have, for example, a hollow cylinder shape. The inductive unit 121 is not limited thereto and may be a pair of plates spaced apart from each other at a certain distance.

The variable magnetic unit 122 may change the path of the emitted electrons EE induced by the inductive unit 121. In detail, the variable magnetic unit 122 may change the travelling direction of the emitted electrons EE within the variable magnetic unit 122 by generating a magnetic field. The emitted electrons EE moving within the magnetic field of the variable magnetic unit 122 may be subject to a Lorentz force. A motion path of the emitted electrons EE may be changed by the Lorentz force acting on the emitted electrons EE.

The emitted electrons EE subjected to the Lorentz force within the variable magnetic unit 122 may reach the detection unit 123. A position at which the emitted electrons EE reach the detection unit 123 may be determined according to the charge amount and kinetic energy of the emitted electrons EE, and the magnitude of a magnetic field. Accordingly, the variable magnetic unit 122 may adjust a position at which the emitted electrons EE reach a flat surface of the detection unit 123 by changing the magnitude of the magnetic field.

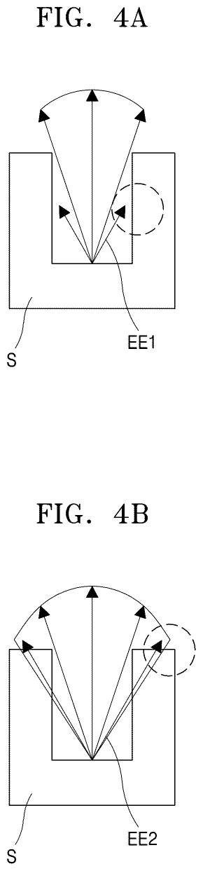

Because SEMs in the related prior art use a plurality of detection units with fixed positions and directions, the SEMs may only measure a charge amount of emitted electrons directed to each of the plurality of detection units. However, because, in an embodiment, the variable magnetic unit 122 may change a magnetic field, the emitted electrons EE may reach different positions on the flat surface of the detection unit 123 according to the kinetic energy of the emitted electrons EE, and thus the travelling direction, the kinetic energy, and charge amount of the emitted electrons EE may all be measured. This is described in detail with reference to FIG. 3.

The detection unit 123 may generate an image by detecting the emitted electrons EE. The detection unit 123 may detect at least a portion of the emitted electrons EE reflected from the wafer W and/or the sample S. For example, the detection unit 123 may detect secondary electrons and/or backscattered particles emitted from the wafer W. According to an embodiment, the detection unit 123 may detect some of the emitted electrons EE that have passed through the variable magnetic unit 122. The detection unit 123 may obtain an SEM image by detecting the emitted electrons EE. That is, the detection unit 123 may detect the emitted electrons EE colliding with a surface of the detection unit 123 and convert the same into an electrical signal to generate an image from the electrical signal.

The detection unit 123 may be an image sensor, such as a charge-coupled device (CCD) or a complementary metal oxide semiconductor (CMOS) sensor. The detection unit 123 may generate a plurality of images in response to a changing magnetic field in the variable magnetic unit 122. That is, when a magnetic field formed by the variable magnetic unit 122 changes, a position at which the emitted electrons EE reach the flat surface of the detection unit 123 changes, and thus the detection unit 123 may generate different images according to the magnetic fields of the variable magnetic unit 122.

The controller 130 may control the electronic beam scanning module 110 so that the input electron beam IEB is irradiated to a certain position on the sample S. The controller 130 may control energy applied to the input electron beam IEB from the electron gun 111, control the focusing lens 112 to focus the input electron beam IEB on the deflector 113, control the deflector 113 to deflect the input electron beam IEB, and control the objective lens 114 to focus the input electron beam IEB on the sample S.

In addition, the controller 130 may control the emitted electron detection module 120. That is, the controller 130 may control the inductive unit 121 that generates an electric field to induce the emitted electrons EE and control the variable magnetic unit 122 that generates a magnetic field to change a movement path of the emitted electrons EE.

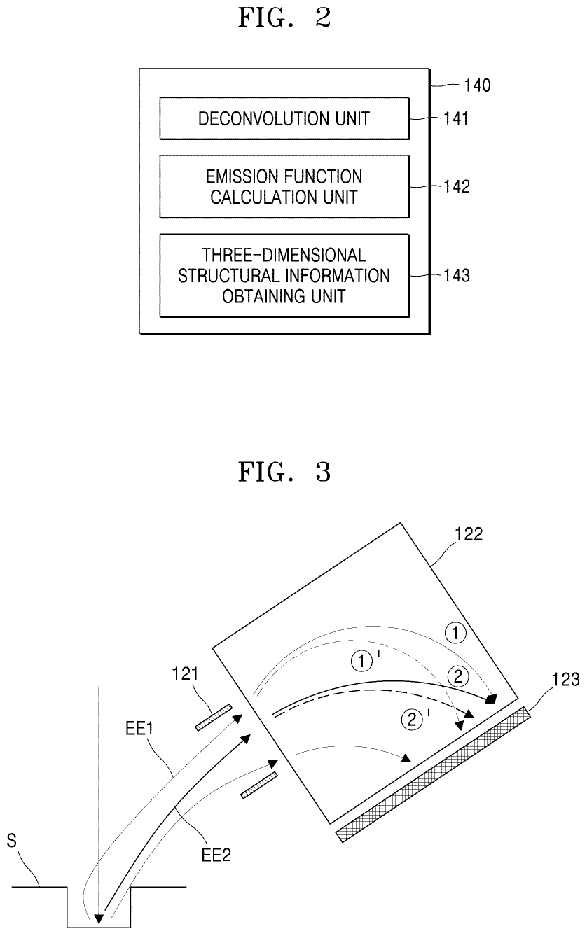

The signal processing unit 140 may process each SEM image for the wafer W and/or the sample S to be inspected. The signal processing unit 140 may convert the SEM image into a grey-level histogram, analyze the grey-level histogram, and calibrate the detection unit 123 to generate an image for three-dimensional structure measurement. The signal processing unit 140 may calibrate the detection unit 123 according to a pattern structure of the wafer W being measured and post-process the image to obtain highly reproducible data. A structure of the signal processing unit 140 is described below with reference to FIG. 2.

The signal processing unit 140 may be a computing device such as a workstation computer, a desktop computer, a laptop computer, a tablet computer, or the like. The signal processing unit 140 may be configured by separate pieces of hardware, or may be separate pieces of software included in one piece of hardware. The signal processing unit 140 may be a simple controller, a micro signal processing unit, a complex signal processing unit such as a central processing unit (CPU), a graphics processing unit (GPU), or the like, a signal processing unit configured by software, dedicated hardware, or firmware. The signal processing unit 140 may be configured by, for example, a general-purpose computer or application-specific hardware such as a digital signal processor (DSP), a field programmable gate array (FPGA), an application-specific integrated circuit (ASIC), or the like.

In some embodiments, an operation of the signal processing unit 140 may be implemented by commands stored on a machine-readable medium, which may be read and executed by one or more signal processing units. Here, the machine-readable medium may include any mechanism for storing and/or transmitting information in a form readable by a machine (e.g., a computing device). For example, the machine-readable medium may include read-only memory (ROM), random-access memory (RAM), a magnetic disk storage medium, an optical storage medium, flash memory devices, electrical, optical, acoustical or other forms of radio signals (e.g., carrier waves, infrared signals, digital signals, or the like), and any other signals.

The signal processing unit 140 may be configured by firmware, software, routines, and commands to perform the operations described for the signal processing unit 140 or any process to be described below. However, this is for convenience of explanation, and it should be understood that the operation of the signal processing unit 140 may be caused by a computing device, a signal processing unit, a controller, or another device executing firmware, software, routines, commands, or the like. Furthermore, the signal processing unit 140 may derive three-dimensional structural information of the sample S by using the SEM image obtained from the detection unit 123 and the magnetic field generated by the variable magnetic unit 122. For example, the signal processing unit 140 may deconvolve, based on Lorentz's law, a plurality of images generated according to the magnitude of the magnetic field of the variable magnetic unit 122 to calculate vector information of the emitted electrons EE and positions at which the emitted electrons EE reach the surface of the detection unit 123. The vector information is a vector of the emitted electrons EE having the kinetic energy of the emitted electrons EE as the magnitude of the vector and an incident direction of the emitted electrons EE incident to the inductive unit 121 as a direction of the vector.

In detail, the detection unit 123 may generate different SEM images according to the magnitudes of the magnetic field of the variable magnetic unit 122. When the magnitude of the magnetic field of the variable magnetic unit 122 changes, the Lorentz force acting on the emitted electrons EE within the variable magnetic unit 122 changes, and thus a trajectory of the emitted electrons EE within the variable magnetic unit 122 may change. As a movement trajectory of the emitted electrons EE changes, a position at which the emitted electrons EE are detected on the surface of the detection unit 123 changes, and thus a new SEM image may be generated. For example, when the magnitude of the magnetic field of the variable magnetic unit 122 is changed five times, the detection unit 123 may generate five SEM images.

The plurality of SEM images, generated according to variations in the magnetic field of the variable magnetic unit 122, include emitted electrons (EE) having various kinetic energy levels. The signal processing unit 140 may deconvolve the plurality of SEM images to calculate positions where emitted electrons EE having the same kinetic energy reach the surface of the detection section 123, wherein the positions correspond to the magnitude of the magnetic field generated by the variable magnetic section 122. In addition, the signal processing unit 140 may calculate vector information of the emitted electrons EE, namely, kinetic energy levels of each emitted electron EE and incidence directions at which the emitted electrons EE enter the inductive section 121.

Then, the signal processing unit 140 may calculate an emission function by calculating the vector information of the emitted electrons EE and the electric field of the inductive unit 121. The emission function is a function that represents a charge amount of the emitted electrons EE and a level of kinetic energy of the emitted electrons EE emitted at each azimuth from an emission point where the emitted electrons EE are emitted from the sample S.

Next, the signal processing unit 140 may quantitatively obtain the three-dimensional structural information of the sample S by calculating a change in amount of the emitted electrons EE (or a change in amount of the emission function) and transmittance information for a material of the sample S. The change in amount of the emission function represents a difference between an emission function at a given position of the sample S and an emission function on a flat surface of the sample S, where there is no three-dimensional structure.

In detail, when emitted electrons EE from the surface of a sample are blocked by a wall structure of a sample pattern, and the number of emitted electrons in a particular direction is zero or small, the signal processing unit 140 may confirm which structure exists in a direction by comparing the emission function under the above conditions with an emission function when the input electron beam IEB is incident on the surface of the sample without a wall structure.

In addition, the signal processing unit 140 may consider the transmittance information for a material of the sample S. The emitted electrons EE exhibit a characteristic wherein their transmittance through the material increases as their kinetic energy increases. Accordingly, the signal processing unit 140 may quantitatively obtain the three-dimensional structural information of the sample S by calculating a change in amount of the emitted electrons EE (or a change in amount of the emission function) and the transmittance information for the material of the sample S.

FIG. 2 is a functional block diagram illustrating the configuration of the signal processing unit 140 according to an embodiment. As shown, this signal processing unit 140 may include, for example, a deconvolution unit 141, an emission function calculation unit 142, and a three-dimensional structural information obtaining unit 143. The deconvolution unit 141 may deconvolve a plurality of images generated according to the magnetic field magnitudes of the variable magnetic unit 122 according to Lorentz's law to calculate vector information of the emitted electrons EE and the position at which the emitted electrons EE reach the surface of the detection unit 123. The emission function calculation unit 142 may calculate an emission function by calculating vector information and the electric field of the inductive unit 121. The three-dimensional structural information obtaining unit 143 may quantitatively obtain the three-dimensional structural information of the sample S by calculating a change in amount of the emitted electrons EE (or a change in amount of the emission function) and the transmittance information for the material of the sample S.

FIG. 3 is a diagram to describe a process in which emitted electrons are detected through an emitted electron detection module. Referring to FIG. 3, a first emitted electron EE1 and a second emitted electron EE2 may have different levels of kinetic energy and different charges amounts. Nevertheless, the first emitted electron EE1 and the second emitted electron EE2, which have passed through the variable magnetic unit 122, may be detected at the same position on the surface of the detection unit 123, even though the second emitted electron EE2 may have a greater level of kinetic energy than the first emitted electron EE1.

When the magnetic field of the variable magnetic unit 122 is adjusted to be larger, a movement path of the second emitted electron EE2 having a greater level of kinetic energy may be less changed than that of the first emitted electron EE1 having a lower level of kinetic energy according to the Lorenz law. That is, the movement path of the first emitted electron EE1 may be changed from path \textcircled{1} to path \textcircled{1}′, and the movement path of the second emitted electron EE2 may be changed from path \textcircled{2} to path \textcircled{2}′. As the first emitted electron EE1 is changed to path \textcircled{1}′ and the second emitted electron EE2 is changed to path \textcircled{2}′, the positions at which the first emitted electron EE1 and the second emitted electron EE2 are detected on the surface of the detection unit 123 may also be changed. Because the first emitted electron EE1 and the second emitted electron EE2 are detected at different positions on the surface of the detection unit 123, a new SEM image may be advantageously generated.

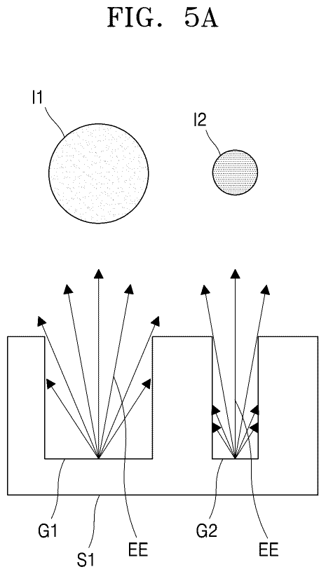

FIGS. 4A and 4B are diagrams to describe emission paths of emitted electrons when the kinetic energy of the emitted electrons is low and high, respectively. Referring to FIGS. 4A and 4B, as the level of kinetic energy of the emitted electrons EE increases, transmittance for a material increases. As shown in FIG. 4A, the first emitted electron EE1 having a relatively low level of kinetic energy may not pass through a wall of the sample S. However, as shown in FIG. 4B, the second emitted electron EE2 having a relatively high level of kinetic energy may pass through the wall of the sample S. Advantageously, as described hereinabove, emission functions may be separated according to the level of kinetic energy of the emitted electrons EE by obtaining a plurality of SEM images while changing the magnetic field of the variable magnetic unit 122 and deconvolving the plurality of SEM images.

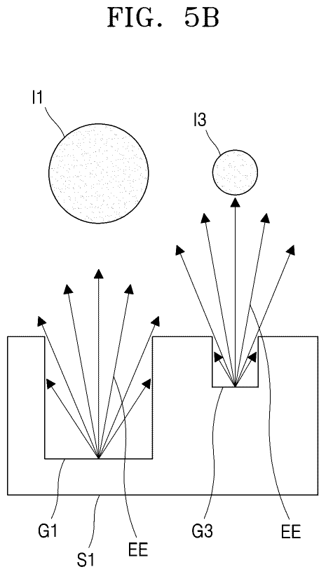

FIGS. 5A and 5B are diagrams to describe SEM images obtained when the depth and critical dimension (CD) of a pattern are different. For example, according to an embodiment, when measuring a sample with a three-dimensional structure by using an SEM, the three-dimensional structure of the sample may be measured advantageously when some of emitted electrons are blocked by the sample structure and cause a reduction in gray scale index of an image. That is, as shown in FIG. 5A, in the case of patterns G1 and G2 with different CDs, even when the depth thereof are the same, a rate at which the emitted electrons EE emitted from the pattern G2 with a smaller CD are blocked is greater than a rate at which the emitted electrons EE are emitted from the pattern G1 with a larger CD, and thus an image 12 generated by detection of the emitted electrons EE may be darker than an image 11 generated by detection of the emitted electrons EE. In addition, as shown in FIG. 5B, when amounts of the emitted electrons EE emitted from two patterns G1 and G3 are the same even when a depth of the pattern G3 with a smaller CD is shallower than a depth of the pattern G1 with a greater CD, the brightness of SEM images 11 and 13 with respect to the two patterns G1 and G3 may be the same. Accordingly, for this reason, predicting a three-dimensional structure of a sample by simply using only a gray scale index is limited.

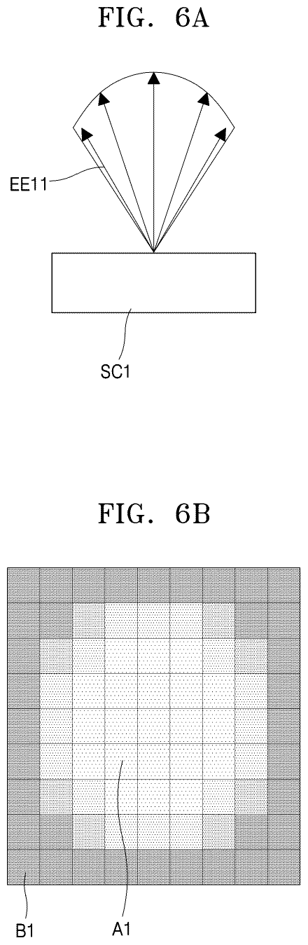

FIGS. 6A to 9B are diagrams to describe SEM images formed by emitted electrons with high kinetic energy and emitted electrons with low kinetic energy according to a three-dimensional structure of a pattern. In particular, FIG. 6A is a diagram schematically illustrating emission of emitted electrons EE11 from a sample SC1 having a wall-less structure, and FIG. 6B is an SEM image generated through detection of the emitted electrons EE11 of FIG. 6A. As shown in FIG. 6A, the emitted electrons EE11 from the sample SC1 with a wall-less structure may be emitted in all directions, and the emitted electrons EE11 emitted in all directions may be detected in large numbers at a center A1 of the detection unit 123, and a detection amount thereof decreases toward a periphery B1, thereby generating an SEM image as shown in FIG. 6B. It may be known that the emitted electrons EE are emitted in all directions through the SEM image.

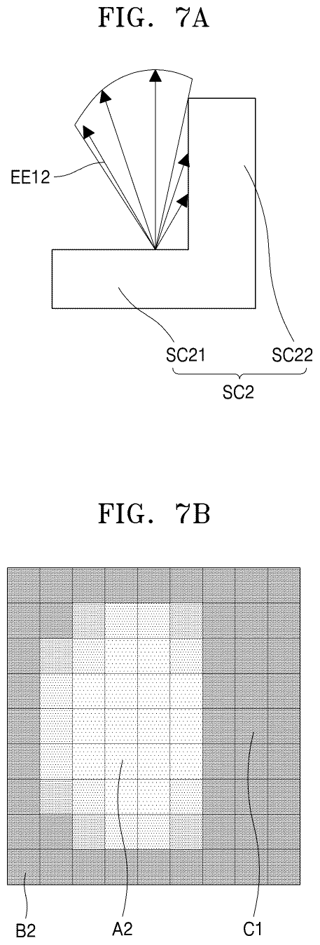

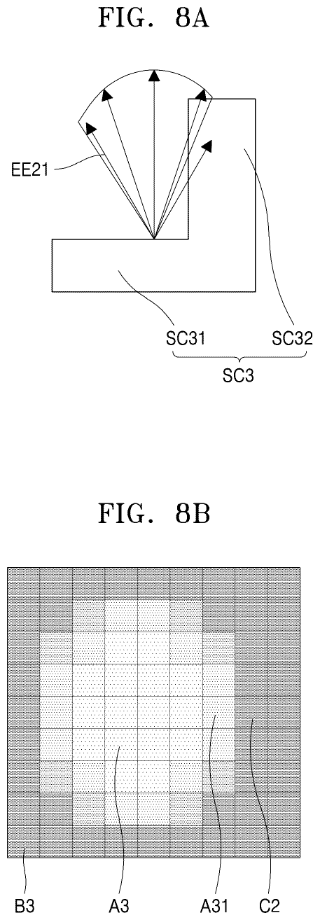

In contrast, FIG. 7A is a diagram schematically illustrating emission of emitted electrons EE12 from a sample SC2 with a structure having a bottom SC21 and a wall S22 on only one side thereof, and FIG. 7B is an SEM image generated through detection of the emitted electrons EE12 of FIG. 7A. As shown in FIG. 7A, in the sample SC2 with the structure having the wall S22 on one side of the bottom SC21, the emitted electrons EE12 having a low level of kinetic energy may not pass through the wall S22, and the emitted electrons EE12 may not be detected in a direction where the wall S22 is located, and thus, it may be confirmed through the SEM image that, as shown in FIG. 7B, there are no emitted electrons EE12 detected on one side C1 of the SEM image, the emitted electrons EE12 are detected in large numbers at a center A2 of the detection unit 123, and a detection amount thereof decreases toward a periphery B2. Next, FIG. 8A is a diagram schematically illustrating emission of emitted electrons EE21 from a sample SC3 with a structure having a bottom SC31 and a wall SC32 on one side thereof, and FIG. 8B is an SEM image generated through detection of the emitted electrons EE21 of FIG. 8A. As shown in FIG. 8A, in the sample SC3 with a structure having the wall SC32 on one side of the bottom SC31, the emitted electrons EE21 with high level of kinetic energy may pass through the wall SC32, and some emitted electrons EE21 may be detected in a direction where the wall SC32 is located. In this case, as shown in FIG. 8B, an SEM image may be confirmed in which some emitted electrons EE21 are detected at a portion A31 between a center A3 of the SEM image, where a large number of emitted electrons EE21 are detected, and outermost peripheries B3 and C2 where the emitted electrons EE21 are not detected.

Although each of the samples SC2 and SC3 of FIGS. 7A and 8A has the same type of wall structure, it may be confirmed that the transmittance of emitted electrons is different depending on the level of kinetic energy of the emitted electrons, and thus different types of SEM images can be generated even when the wall structure has not changed.

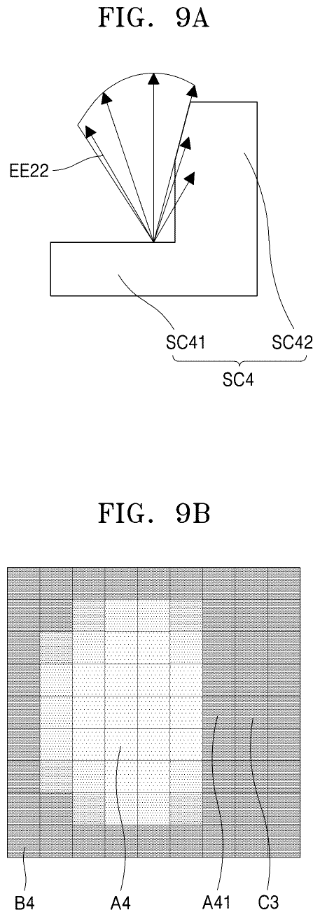

FIG. 9A is a diagram schematically illustrating emission of emitted electrons EE22 from a sample SC4 having a bottom SC41, a wall on one side thereof, and a chamfered structure SC42 at a corner of the wall, and FIG. 9B is an SEM image generated through detection of the emitted electrons EE22 of FIG. 9A. In particular, when the corner of the wall is chamfered as shown in FIG. 9A, the emitted electrons EE22 move in a chamfered direction, but the emitted electrons EE22 may not pass through in a direction of a thick wall. In this case, as shown in FIG. 9B, an SEM image may be confirmed in which no emitted electrons EE22 are detected in a portion A41 between a center A4 of the SEM image, where a large number of emitted electrons EE22 are detected, and outermost peripheries B4 and C3 where the emitted electrons EE22 are not detected.

In an embodiment, since independent signals may be measured according to a level of kinetic energy of emitted electrons, various forms of changes in emission function according to the level of kinetic energy of emitted electrons may be measured. In addition, the thickness of a sample in a particular direction may be checked by checking a signal in which an emission function decreases in each direction, and this may be used to measure a three-dimensional shape of a complex structure.

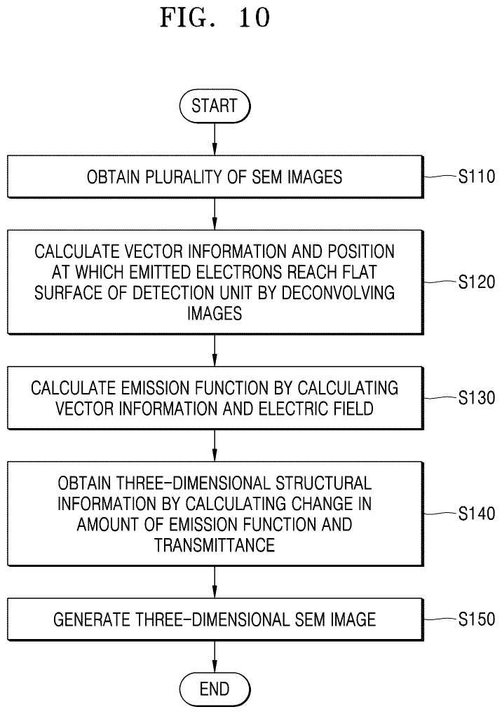

FIG. 10 is a flowchart to describe a method of obtaining a three-dimensional SEM image by using an SEM, according to an embodiment. Descriptions are made with reference to FIG. 1, and descriptions already been given with reference to FIGS. 1 to 9 are briefly given or omitted. Referring to FIG. 10, a method of obtaining a three-dimensional SEM image by using an SEM, according to an embodiment, may include operation S110 of obtaining a plurality of SEM images, operation S120 of deconvolving the plurality of SEM images, operation S130 of calculating an emission function, operation S140 of obtaining a three-dimensional structural degree, and operation S150 of generating a three-dimensional SEM image.

Operation S110 of obtaining a plurality of SEM images may include obtaining a plurality of SEM images while changing the magnitude of a magnetic field of the variable magnetic unit 122, as described above. In particular, a series of operations for wafer inspection, such as wafer loading, alignment, and beam/stage adjustment, may be performed first. When the wafer is placed on a stage after wafer inspection, the controller 130 may simultaneously adjust the electron beam scanning module 110 to scan a predetermined position on the wafer and may adjust the magnitude of the magnetic field of the variable magnetic unit 122 to a predetermined magnitude. The input electron beam IEB generated by the electron beam scanning module 110 may pass through an electron optical system and be focused and irradiated onto a sample, and emitted electrons EE may be emitted from a surface of the sample. The emitted electrons EE may pass through the inductive unit 121 and the variable magnetic unit 122 and be changed in direction, and may be incident on the detection unit 123 and be converted into an electrical signal according to the energy level and emission direction of the electrons, and the magnitude of the magnetic field.

Operation S120 of deconvolving the plurality of SEM images may include deconvolving a plurality of images generated according to the magnetic field magnitudes of the variable magnetic unit 122 according to Lorentz's law to calculate vector information of the emitted electrons EE and the position at which the emitted electrons EE reach the surface of the detection unit 123. Operation S130 of calculating the emission function may include calculating an emission function by calculating vector information and the electric field of the inductive unit 121. Operation S140 of obtaining the three-dimensional structural degree may include quantitatively obtaining three-dimensional structural information of the sample S by calculating a change in amount of the emitted electrons EE (or a change in amount of the emission function) and the transmittance information for the material of the sample S. Finally, operation S150 of generating the three-dimensional SEM image may include generating a three-dimensional SEM image by using the plurality of SEM images and the three-dimensional structural information of the sample S.

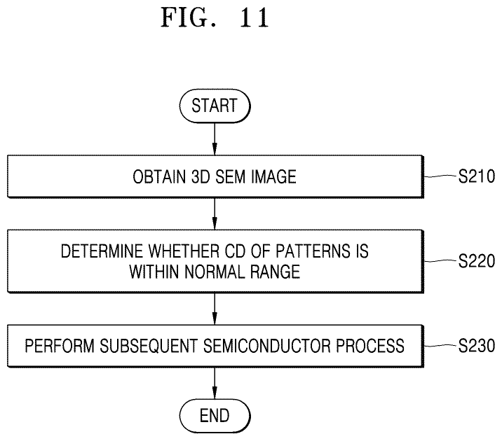

FIG. 11 is a conceptual diagram to describe a method of manufacturing a semiconductor device by using an SEM, according to an embodiment. Descriptions are made with reference to FIG. 1, and descriptions already given with reference to FIGS. 1 to 10 are briefly given or omitted. Referring to FIG. 11, a method of manufacturing a semiconductor device using an SEM, according to an embodiment (hereinafter referred to as a ‘semiconductor device manufacturing method’), may include operation S210 of obtaining a three-dimensional SEM image, which includes operations of the method of obtaining a three-dimensional SEM image of FIG. 10.

After obtaining the three-dimensional SEM image, it is determined whether the CD of patterns on a wafer is within a normal range based on the three-dimensional SEM image in operation S220. When the CD of the patterns is within the normal range, a subsequent semiconductor process is performed on the wafer. The subsequent semiconductor process may include various processes. For example, the subsequent semiconductor process may include a deposition process, an exposure process, an etching process, an ion process, a cleaning process, or the like. In addition, the subsequent semiconductor process may include a singulation process of individualizing a semiconductor substrate in a wafer form into individual semiconductor chips, a test process of testing the semiconductor chips, and a packaging process of packaging the semiconductor chips. A semiconductor device may be completed through the subsequent semiconductor process on a semiconductor substrate. Thus, when the CD of the patterns is out of the normal range, that is, when the CD of hole patterns formed on the wafer is defective, it is a problem with a patterning process, and thus the semiconductor device manufacturing method of the embodiment may be terminated, and the corresponding patterning process may proceed to analyze the cause or the like to resolve the problem.

While the inventive concept has been particularly shown and described with reference to embodiments thereof, it will be understood that various changes in form and details may be made therein without departing from the spirit and scope of the following claims.

What is claimed is:

1. A scanning electron microscope, comprising:
an inductive unit configured to apply an electric field to electrons emitted from a sample, in response to an electron beam directed at the sample;
a variable magnetic unit configured to change a path of the emitted electrons affected by the inductive unit, using a magnetic field;
a detection unit configured to generate an image by detecting the emitted electrons having the changed path; and
a signal processing unit configured to derive three-dimensional structural information from the sample using the image and the magnetic field generated by the variable magnetic unit.

2. The scanning electron microscope of claim 1, wherein the inductive unit has a net positive charge; and wherein the emitted electrons are directed to the variable magnetic unit by the electric field applied by the inductive unit.

3. The scanning electron microscope of claim 1, wherein the variable magnetic unit is configured to adjust a position at which the emitted electrons reach a flat surface of the detection unit by changing a magnitude of the magnetic field generated by the variable magnetic unit.

4. The scanning electron microscope of claim 1, wherein the detection unit includes at least one sensor selected from a group consisting of a charge-coupled device (CCD) image sensor and a complementary metal oxide semiconductor (CMOS) image sensor.

5. The scanning electron microscope of claim 1, wherein the detection unit is configured to generate a plurality of images in response to a changing magnetic field in the variable magnetic unit.

6. The scanning electron microscope of claim 5,
wherein the signal processing unit is configured to deconvolve the plurality of images generated according to a magnitude of the magnetic field according to Lorentz's law to calculate vector information of the emitted electrons and a position at which the emitted electrons reach a surface of the detection unit; and
wherein the vector information includes a level of kinetic energy of the emitted electrons as a vector magnitude and an incident direction of the emitted electrons incident to the inductive unit as a vector direction.

7. The scanning electron microscope of claim 6,
wherein the signal processing unit is configured to calculate an emission function by calculating the vector information and the magnetic field of the inductive unit; and
wherein the emission function represents a charge amount of the emitted electrons emitted at each azimuth from an emission point where the emitted electrons are emitted from the sample and a level of kinetic energy of the emitted electrons.

8. The scanning electron microscope of claim 7,
wherein the signal processing unit is configured to quantitatively obtain the three-dimensional structural information of the sample by calculating a change in amount of the emission function and transmittance information for a material of the sample; and
wherein the change in amount of the emission function comprises a difference between an emission function at a certain position of the sample and an emission function on a flat surface of the sample without a three-dimensional structure.

9. A scanning electron microscope, comprising:
an electron beam scanning module configured to scan an input electron beam on a sample;
an emitted electron detection module configured to change and detect a path of emitted electrons emitted from the sample by the input electron beam by using a magnetic field;
a controller configured to control the electron beam scanning module to allow the input electron beam to be irradiated to a certain position on the sample and to control a magnitude of the magnetic field generated by the emitted electron detection module; and
a signal processing unit configured to derive three-dimensional structural information of the sample by using an image generated by the emitted electron detection module and the magnetic field.

10. The scanning electron microscope of claim 9, wherein the electron beam scanning module comprises:
an electron gun configured to generate the input electron beam and irradiate the input electron beam onto the sample;
a stage configured to support the sample;
a focusing lens arranged between the electron gun and the sample and configured to focus the input electron beam;
a deflector arranged between the focusing lens and the sample and configured to deflect the input electron beam; and
an objective lens arranged between the deflector and the sample and configured to focus the input electron beam onto the sample.

11. The scanning electron microscope of claim 9, wherein the emitted electron detection module comprises:
an inductive unit configured to apply a electric field to the emitted electrons;
a variable magnetic unit configured to change a path of the emitted electrons affected by the inductive unit using a magnetic field generated by the variable magnetic unit; and
a detection unit configured to generate an image by detecting the emitted electrons having a changed path.

12. The scanning electron microscope of claim 11, wherein the variable magnetic unit is configured to adjust a position at which the emitted electrons reach a flat surface of the detection unit by changing a magnitude of the magnetic field generated by the variable magnetic unit.

13. The scanning electron microscope of claim 11, wherein the detection unit is configured to generate a plurality of images in response to a changing magnetic field in the variable magnetic unit.

14. The scanning electron microscope of claim 13,
wherein the signal processing unit is configured to deconvolve the plurality of images generated according to a magnitude of the magnetic field according to Lorentz's law to calculate vector information of the emitted electrons and a position at which the emitted electrons reach a surface of the detection unit; and
wherein the vector information includes a level of kinetic energy of the emitted electrons as a vector magnitude and an incident direction of the emitted electrons incident to the inductive unit as a vector direction.

15. The scanning electron microscope of claim 14,
wherein the signal processing unit is configured to calculate an emission function by calculating the vector information and the electric field of the inductive unit; and
wherein the emission function represents a charge amount of the emitted electrons emitted at each azimuth from an emission point where the emitted electrons are emitted from the sample and a level of kinetic energy of the emitted electrons.

16. The scanning electron microscope of claim 15,
wherein the signal processing unit quantitatively obtains the three-dimensional structural information of the sample by calculating a change in amount of the emission function and transmittance information for a material of the sample; and
wherein the change in amount of the emission function includes a difference between an emission function at a certain position of the sample and an emission function on a flat surface of the sample without a three-dimensional structure.

17. A scanning electron microscope, comprising:
an electron gun configured to generate an input electron beam and scan the input electron beam onto a semiconductor process resultant;
a stage configured to support the semiconductor process resultant;
a focusing lens arranged between the electron gun and the semiconductor process resultant and configured to focus the input electron beam;
a deflector arranged between the focusing lens and the semiconductor process resultant and configured to deflect the input electron beam;
an objective lens arranged between the deflector and the semiconductor process resultant and configured to focus the input electron beam onto the semiconductor process resultant;
an inductive unit configured to induce emitted electrons emitted from the semiconductor process resultant by the input electron beam with an electric field;
a variable magnetic unit configured to change a path of the emitted electrons induced by the inductive unit by using another magnetic field;
a detection unit configured to generate an image by detecting the emitted electrons having a changed path;
a controller configured to control the input electron beam to be irradiated to a certain position on the semiconductor process resultant and to control a magnitude of the magnetic field generated by the variable magnetic unit; and
a signal processing unit configured to derive three-dimensional structural information of the semiconductor process resultant by using the image and the magnetic field generated by the variable magnetic unit.

18. The scanning electron microscope of claim 17,
wherein the signal processing unit is configured to deconvolve a plurality of images generated according to a magnitude of the magnetic field according to Lorentz's law to calculate vector information of the emitted electrons and a position at which the emitted electrons reach a surface of the detection unit; and
wherein the vector information comprises a level of kinetic energy of the emitted electrons as a vector size and an incident direction of the emitted electrons incident to the inductive unit as a vector direction.

19. The scanning electron microscope of claim 18,
wherein the signal processing unit is configured to calculate an emission function by calculating the vector information and the electric field of the inductive unit; and
wherein the emission function represents a charge amount of the emitted electrons emitted at each azimuth from an emission point where the emitted electrons are emitted from the semiconductor process resultant and a level of kinetic energy of the emitted electrons.

20. The scanning electron microscope of claim 19,
wherein the signal processing unit is configured to quantitatively obtain the three-dimensional structural information of the semiconductor process resultant by calculating a change in amount of the emission function and transmittance information for a material of the semiconductor process resultant; and
wherein the change in amount of the emission function comprises a difference between an emission function at a certain position of the semiconductor process resultant and an emission function on a flat surface of the semiconductor process resultant without a three-dimensional structure.
